(19) United States
(12) Patent Application Publication
(10) Pub. No.: US 2026/0293663 A1
(43) Pub. Date: Sep. 24, 2026

(54) HARD-CODING AN IC-SPECIFIC CODE IN AN INTEGRATED CIRCUIT, DEVICE

(71) Applicant: SANDGRAIN B.V., Eindhoven (NL)

(72) Inventors: Casparus Anthonius Henricus JUFFERMANS, Eindhoven (NL); Pieter Werner HOOIJMANS, Eindhoven (NL); Jeroen Mathias DOUMEN, Eindhoven (NL)

(21) Appl. No.: 19/476,196

(22) PCT Filed: Apr. 17, 2024
(86) PCT No.: PCT/IB2024/053760

§ 371 Date: Oct. 17, 2025

(30) Foreign Application Priority Data
Apr. 18, 2023 (NL) 2034619

(51) Int. Cl. H10W 20/49; H10W 20/00

(52) U.S. Cl. CPC H10W 20/493; H10W 20/067

(57) ABSTRACT

Method of manufacturing an integrated circuit having a predetermined IC-specific code hard-coded into the structure of the IC, comprising the steps of forming a plurality of identical integrated circuits in a plurality of first layers on a wafer using a first processing part; processing the wafer in a second processing part, forming a plurality of programmable conductive connections in a further circuit layer, each making interconnections between two or more circuit portions of the plurality of identical circuits. The plurality of programmable connections comprise a target portion, arranged in an array at predetermined positions on the wafer; exposing a selected set of the target portions different for different ones of the plurality of identical integrated circuits on the wafer; etching portions of the connections at the exposed portions removing interconnections, implementing an IC-specific code in each of identical ICs; and cutting the wafer to separate the ICs.

### TECHNICAL FIELD

The present invention relates to a method of manufacturing an integrated circuit having an IC-specific code hard-coded into the structure of the integrated circuit, and an integrated circuit having an IC-specific code hard-coded into the structure of the integrated circuit.

### BACKGROUND ART

Such a secure system is e.g. pre-published by patent publication WO2021240445, which discloses the use and definition of a trustworthy chip, typically for an end node, which can thereby be identified, preferably also authorized, using a central registration system or server, and encrypted communication. A chip, i.e. electronic device as defined by this publication, thereto comprises a pre-determined, preferably hard coded, immutable secure element, which apart from an identification value, may contain various codes such as a customer code, and which comprises one or more keys or headers for enabling encrypted communication with the central server, thus forming a trust anchor as it were in the secure system, e.g. as defined by this publication. One object of the present invention is involved with realizing a generic design of a semi-conductor device which may be programmed for this purpose as known per se.

While integrated circuits provided with a hard coded identification are known, e.g. from the US20080121709 patent publication, such designs often render these codes to be identical in integrally manufactured sets of integrated circuits, or come with uneconomical or practically disadvantageous circumstances in that such chips are produced with a maskless lithography process using e.g. an electron beam machine. While multi-electron beam systems have been proposed, such systems are to date not practiced in large scale IC manufacturing. In other cases such as indicated by patent publication U.S. Pat. No. 5,642,307 the integrated circuits may disadvantageously require post processing in they are produced so-called fuse programmable. In tackling this situation, the following may be observed. Semiconductor device fabrication is the process used to manufacture semiconductor devices, such as the complementary metal-oxide-semiconductor (CMOS) process used to make integrated circuit (IC) chips (terms “IC” and “chip” are used interchangeably herein). This involves a lengthy sequence of lithographic and chemical processing steps (such as deposition, applying resist, baking the resist, lithographic exposure, developing the resist, washing, etching, resist stripping, etc.) during which electronic circuits are gradually created in multiple layers on a wafer made of semiconducting material. A very large number of ICs are usually formed on a single wafer. A silicon wafer is mostly used, but various compound semiconductors are used for specialized applications.

With reference to FIG. 1, the manufacturing process of an IC can be divided into two main parts. These two parts of the manufacturing process are commonly known as front-end processing 1 and back-end processing 2.

The front-end processing includes wafer fabrication 10, the process of forming a large number of ICs (comprising transistors and electrical interconnections) on the silicon wafer in a semiconductor fab. After forming the electronic circuits on the wafer, a protective passivation layer is formed over the top layer of the circuits, to seal the wafer to prevent the ICs formed on the wafer from contamination or moisture.

The back-end processing 2 includes assembly 20, the automated process of cutting (dicing) the wafer to separate the individual ICs, wire bonding to connect conducting bond pads on the IC to conducting leads to enable electrical connections to be made from the IC to external components, and packaging to encapsulate each IC in ceramic or plastic package. The ICs are then ready for sale and later assembly into final end-products.

The front-end processing 1 typically includes two phases: front-end-of-line (FEOL) and back-end-of-line (BEOL). The FEOL is the first portion of IC fabrication where the individual devices (transistors, capacitors, resistors, etc.) are patterned in the semiconductor. FEOL generally covers everything up to (but not including) the deposition of metal interconnect layers. For the CMOS process, FEOL contains all fabrication steps needed to form fully isolated CMOS elements, including well formation, gate module formation and source and drain module formation.

Once the various semiconductor devices have been created, they must be interconnected to form the desired electrical circuits. This occurs in a series of wafer processing steps collectively referred to as BEOL (not to be confused with back-end of chip fabrication, which refers to the packaging and testing stages). BEOL processing involves creating multiple layers of conducting interconnecting lines, typically metal, that are isolated from other conducting layers by intervening dielectric layers.

The front-end processing is performed in a semiconductor fab under stringent clean room conditions, whereas the back-end processing is usually performed in a separate facility with less strict environmental control. When the front-end processing is finished in the semiconductor fab, the wafer, with passivation layer applied to protect the underlying layers, is transported to a back-end processing facility for assembly.

The two parts typically include two test steps: wafer probing 19 performed on the completed wafer in the semiconductor fab, and final test 29 performed on the individual ICs in the back-end assembly facility.

If a chip requires a unique or specially selected code for authentication purposes, such code may be software programmed into a memory of the chip. However, the programming method typically results in a code that can be hacked and changed during use.

Alternatively, a unique or specially selected code can be hard-coded into the chip so that it is much more difficult or impossible to change after manufacture. Such codes are essentially programmed into the structure of the chip, i.e. in the layers that comprise the chip, during manufacturing of the chip. Hard coding of a chip, e.g. for providing the chip with a digital identity, is known in semiconductor manufacturing processes.

However, realization of such chips with an electronically accessible, pre-determined and effectively unchangeable identity code has not occurred on a large scale. Such electronically coded chips available at the present time are typically based on after-manufacturing processing that results in significant disadvantages. The conventional process for manufacturing ICs uses mask-based lithography systems, in which a fixed mask is used repeatedly to expose each small area of a wafer to form the required structures of a large number of ICs being manufactured on the wafer. The high cost of the masks and the technique of using the same mask repeatedly to scan the whole surface of the wafer, and for the same again for each wafer of a batch of wafers, makes it cost and time prohibitive to use mask-based lithography to hard-code IC-specific codes into ICs.

In an attempt to overcome this problem, a process has been proposed by patent publication WO 2018/117275 A1 for realizing unique chips by the use of a proposed massively parallel electron beam lithography system performing exposures using many thousands or even millions of electron beams operating in parallel. Drawbacks of the process disclosed in this publication using a massively parallel electron beam lithography system are the complexity of the systems and of the exposure process using such systems, the need of huge amounts of data and corresponding huge quantity of memory and data transmission capacity to control so many beams, the difficulties associated with integrating different types of exposure equipment within a front-end manufacturing process (requiring corrections in the electron beam writing to meet overlay requirements), and the commercial unavailability of such machines.

In another solution towards physically altering the structure of an integrated circuit device, fuses have been used. This method is known from correcting defective memory blocks in a chip, where the fuses are selectively blown using a laser or electrical current passed through the fuse. US 2006/0267136 A1 discloses an integrated circuit with fuses formed under the passivation layer. The fuses are used, after testing of the completed integrated circuit, to isolate defective rows or columns of RAM memory cells and connect spare memory cells. U.S. Pat. No. 7,183,623 B2 discloses the use of fuses for trimming of integrated circuits to account for variations in electrical characteristics of the circuitry measured after manufacture of the integrated circuit. The large fuse probe pads and wide metal lines to accommodate the large currents necessary for fuse blowing contribute disproportionally to the die size, and savings in integrated circuit die area is achieved by positioning the fuses and associated circuitry adjacent to the scribe lane between integrated circuits, and locating the fuse pads and power supply pads within the scribe lane.

A physically unclonable function (PUF) has also been used to determine the physical characteristics of a chip after manufacture and use the minute variations inherent in the manufacturing process to derive a unique or quasi-unique code for each chip. However, the codes and the associated process do not provide a way to deterministically create a chip having a predetermined IC-specific code hard-coded into the integrated circuit. Rather the codes derived using this method are inherently unpredictable and cannot always be reliably reproduced when the chip is put into use in varying environmental conditions.

### SUMMARY OF THE INVENTION

The present invention overcomes the limitations of the prior art by enabling predetermined IC-specific codes to be permanently hard-coded into individual chips using available lithographic techniques and processes, while realizing electronically individualized chips. The invention enables the conventional, highly optimized front-end process flow to be used unaltered to manufacture the majority of the structure of the ICs, and adds a special mid-end processing flow to hard code a predetermined IC-specific code into each chip.

According to an aspect of the invention, a method of manufacturing an integrated circuit, having a predetermined IC-specific code hard-coded into the structure of the integrated circuit, is proposed. The method comprises the steps of forming a plurality of identical integrated circuits in a plurality of first layers on a wafer using a first processing part; providing the wafer including the plurality of identical integrated circuits for processing in a second processing part; and processing the wafer in the second processing part. This processing in the second processing part comprises forming a plurality of programmable conductive connections in at least one further circuit layer on the wafer, wherein the plurality of programmable conductive connections each make interconnections between two or more circuit portions of the plurality of identical integrated circuits, and wherein the plurality of programmable conductive connections each comprise a target portion, the target portions being arranged in an array at predetermined positions on the wafer; exposing a selected set of the target portions, wherein the selected set of the target portions is different for different ones of the plurality of identical integrated circuits on the wafer; etching the wafer to remove portions of the programmable conductive connections at the exposed target portions to remove the interconnections between the circuit portions of the plurality of identical integrated circuits, wherein the remaining interconnections and the removed interconnections implement a hard-coded binary code in each one of the plurality of identical integrated circuits; and cutting the wafer to separate the integrated circuit from the remaining ones of the plurality of identical integrated circuits.

The IC-specific code is permanently and immutably stored in the IC. The IC-specific code is preferably a binary code, and is preferably of the same predetermined length for all ICs on the wafer. The IC-specific code hard-coded in each one of the plurality of identical ICs is preferably different in different ones of the plurality of identical ICs, and a different code may be hard-coded in each one of the plurality of identical ICs. In this way the chips are individualized by each having an individualized code specific to each chip which is hard coded into the chip. For example, each IC of the wafer may have a different code which is hard-coded into that IC, or the ICs on the wafer may form small sets in which the code is different for each set on the wafer. In this way, the code which is hardcoded into each IC is specific to that IC. Preferably the method comprises manufacturing a plurality of wafers, each wafer having a plurality of ICs, wherein the codes hard-coded into the ICs on each wafer are different from the codes hard-coded into the ICs on all of the other wafers. In this way, chips may be made each having a unique IC-specific code. The codes may preferably be flexibly assigned to the individual ICs during manufacture of the ICs, for example so that the process of assigning the predetermined IC-specific codes to the ICs can be determined based on the requirements for the final end-products in which the ICs will be used.

The manufacturing process used in the first processing part is preferably a conventional front-end process using conventional mask-based lithography. Lithography using masks is preferred for the first processing part as this is a well-established and highly developed manufacturing process which is best suited for manufacturing large quantities of ICs having identical circuits, at low-cost and high yield. By using a mask-based process to form the identical parts of the ICs, the high cost of the masks is amortised over a very large number of ICs which can be produced from a set of masks. The first processing part preferably uses a CMOS process to form the identical ICs.

The second processing part uses a maskless lithography process for the process of programming the programmable conductive connections, i.e. removing selected interconnections formed by the programmable conductive connections. Since it is desired to hard-code the IC-specific (binary) code into the ICs, and the code will be different for different ones of the ICs on a wafer and preferably different for different wafers, the cost of masks cannot be amortised over a large number of ICs. This makes it prohibitively expensive to use mask-based lithography for the second processing part. Instead, maskless lithography is used and this is made feasible by the design of the ICs, having a limited number of larger dimension target areas for exposure. For example, a maskless electron beam exposure tool may be used having a single beam or shaped beam, or an optical maskless exposure tool using a scanning modulated laser beam or micro-mirror modulated light beam.

In this way, the portion of the structure of the ICs which needs to be individualized, and the manufacturing steps to accomplish the individualization, are reduced to a minimal amount, so that high-volume low-cost conventional techniques can be used for making a maximal amount of the structure of the ICs and used for a maximal number of the manufacturing steps. Under these conditions is becomes practical to use maskless lithography for the minimal remaining structure which is individualized per chip.

The programmable conductive interconnections are formed at an upper metal layer of the wafer and IC, preferably the top metal layer, where the dimensions may be larger than for the lower metal layers. By decoupling the mid-end processing in which the programmable conductive interconnections are formed, from the front-end processing, the design rules used in the front-end processing need not apply for the making the programmable conductive connections. For example, the minimum feature size of the further circuit layer with the programmable conductive connections may be 2 microns. Patterning of the at least one further circuit layer to form the programmable conductive connections is preferably performed using conventional mask-based lithography. This is feasible since the layout of the programmable conductive connections (before etching) is typically identical for every IC on the wafer, and it is desireable to make use of established processes as explained above. Due to the larger dimensions applicable for the further circuit layer, lower resolution and older technology lithography tools and processes which are widely-available may be used for patterning the programmable conductive connections, reducing the cost of the second processing part.

The target portions used for “programming” the programmable conductive connections, i.e. etching to remove the interconnections formed by selected ones of the programmable conductive connections, are also subject to less stringent dimensional constraints as the etching is performed on an upper (or top) metal layer where the dimensions are larger, e.g. measured in microns rather than nanometers.

The target portions are preferably low in number. For example, an IC may have 128 programmable conductive connections and 128 target portions, one target portion for each programmable conductive connection. By exposing and etching selected ones of the 128 target portions, to either remove (break) or not remove selected interconnections made by the 128 programmable conductive connections, a 128-bit IC-specific binary code can be permanently hard-coded into the structure of the IC. This requires lithographic exposure of only the selected ones of the 128 target portions, e.g. exposing an average of 64 target portions per IC. This can be accomplished, for example, using a maskless single-beam or shaped-beam charged-particle beam exposure tool, or a maskless optical exposure tool using a scanning modulated laser beam or micro-mirror modulated light beam. Of course a lesser or greater number of programmable conductive connections and target portions may be used, e.g. 256 for a 256-bit binary code, 1024 for a 1024-bit binary code, etc.

The target portions are preferably relatively small in size (although the design rules used in the mid-end processing provide for much larger minimum dimensions in comparison to the underlying identical layers of the IC), only being large enough to enable etching of the corresponding programmable conductive connection. The programmable conductive connections are preferably formed with an elongated line of metal, each target portion being slightly wider than the width of the elongated line. For example, the elongated line may be 4 microns in length and 1 micron in width, with a target portion 3 microns wide and 2 microns long over the central portion of the elongated line. The target portions are preferably arranged in a regular pattern, for example in a regular array with the same distance separating each target portions from adjacent target portions in x and y directions.

The above feature of the design provides several significant advantages. The lower resolution required, and the low number of small discrete areas laid out in a sparse regular pattern, reduces the time and complexity required for a maskless lithography tool to expose the target portions for each IC. Exposure of the target portions on the wafer may be performed with a minimum number of scans over the wafer. These factors result in the use of a relatively slow and low resolution maskless lithography tool for high-volume low-cost manufacture of the ICs. The use of maskless (direct write) lithography also enables the IC-specific codes to be flexibly assigned to the individual ICs during manufacture of the ICs, by programming the maskless lithography tool to individualize the set of selected target portions to be exposed for each IC on each wafer.

The design of the IC and the method of manufacture thus combines the conventional mask-based first processing part with the novel second processing part for high-volume low-cost manufacture of the ICs having different IC-specific codes hard-coded into each IC. This results in a technically and logistically favorable way of combining a conventional front-end manufacturing process using mask-based lithography, with a flexible mid-end manufacturing process using maskless lithography, enabling low-cost high-volume manufacture of chips each having a predetermined IC-specific code which is hard-coded into the structure of each chip.

The programmable conductive connections each make interconnections between two or more circuit portions of the plurality of identical ICs. The ICs may be designed to each implement a read-only memory. The plurality of identical ICs in combination with their respective remaining and removed interconnections may each form a read-only memory storing a hard-coded binary code. In this way, each programmable conductive connection may form an interconnection within one memory cell of one of the identical ICs, and by removing (breaking) selected ones of the interconnections, each memory cell may be set to permanently store a “1” or a “0” so that the IC-specific code is programmed into the read-only memory.

It is remarked that an in hindsight seemingly comparable process has earlier been made public by patent publication US2020043562. The subject hereof, with an object of producing unique radio frequency emitting semiconductor devices, teaches to sever a one time programmable structure by etching, altering a readable chip identification number of an electrical circuit of the device. Where, by the very nature of the device, it is not an object of this disclosure to keep the unique value secret, the publication provides no teaching as to how to achieve the latter. In particular is not taught to separate the manufacturing in a two step process, of which the second can be performed in an as to secrecy of the unique codes controlled environment, nor is it suggested how to realize such split up.

While it could be acceptable to break the security codes of a single end node device, it is not so when the unique codes of all of the devices can be obtained, e.g. by hacking, as is in principle possible during manufacture of the devices. For this reason the present invention proposes to split up manufacture of the devices in a largest and generic part that can be produced by any foundry, and the manufacture and device specific coding of a second part of the all of the devices in a second, in fact normally final manufacturing step and facility in which an appropriate level of security of the set of coding data for each one of the to be programmed devices can be guaranteed. The invention hence equally encompasses the very idea of splitting up the processes, in particular so in a smart manner of splitting up, and realizes such by not only applying an RDL or redistribution layer technology known per se, but also by departing from a first manufacturing step that is finalized by a passivation layer, i.e. including coverage of any bond pads, and by the provision in said second manufacturing step of using a metal layer, for realizing programmable connections, on top of the passivation layer, while locally opening the passivation layer, i.e. under the controlled conditions of the second manufacturing step, for connection of the metal layer, in fact the conducting lines thereof, to via's, i.e. vertical connections, that end just below the passivation layer. The metal layer on top of the passivation layer is in accordance with the invention, according to preferred embodiment brought on, preferably in pre-defined shape, by the generic foundry, i.e. as part of the first step.

The measure according to the invention hence not only solves the security, in fact trustworthiness problem at manufacturing the devices according to the invention, but also provides freedom and flexibility, at least as to location of securely finishing and coding the devices. This could in principle also be a separate location or process step within the same foundry if additional security measures can be guaranteed. Typically foundries are not adapted to such a task, so that the invention provides a solution to still perform this secure coding of devices in a now so-called “trusted environment”, alternatively trusted factory.

For all of these reasons, the skilled person, considering the secrecy problem underlying the present invention is deemed not to be inclined to depart from the present publication at solving the same. Certainly it may not be obvious from the present publication how to solve a second problem underlying the present invention, of qualitatively transferring a first stage processed wafer to a second factory where the each of the chips of the wafer is to made unique.

In one embodiment a passivation layer is formed over the first layers on the wafer in the first processing part, and the plurality of conductive connections formed in the second processing part are formed at least in part on the passivation. This enables the circuits and structures formed in the first processing part to the protected while the wafer to transferred to the second processing part and undergoes processing there. The method may further comprise forming a second passivation layer over the first passivation layer and the plurality of conductive connections, and may further comprise forming an etch stop layer formed over the first passivation layer, the plurality of programmable conductive connections being formed over the second passivation layer.

The second processing part may use substantially similar materials and substantially similar processing steps as used in the first processing part.

According to another aspect of the invention, an integrated circuit is provided having a hard-coded IC-specific code hard-coded into the structure of the integrated circuit, wherein the integrated circuit is manufactured according to the method as described above.

According to another aspect of the invention, an integrated circuit is provided having a hard-coded IC-specific code hard-coded into the structure of the integrated circuit. The integrated circuit comprises a plurality of identical circuits formed in a plurality of first layers, and a plurality of programmable conductive connections each making an electrical interconnection between two or more circuit portions of a respective one of the plurality of identical circuits. The plurality of conductive connections each comprise a target portion, the target portions being arranged in an array at predetermined positions on a single layer, wherein selected ones of the target portions have been etched to remove portions of the respective conductive connection at the respective target portion to break the interconnection between the respective circuit portions of the respective identical circuit, and wherein the remaining interconnections and the removed interconnections, in conjunction with the plurality of identical circuits, implement the hard-coded IC-specific code in the integrated circuit.

The integrated circuit may further comprise a passivation layer formed over the first layers, and wherein the plurality of conductive connections are formed at least in part over the passivation layer.

The plurality of identical circuits in combination with their respective remaining and removed interconnections may form a read-only memory storing the hard-coded IC-specific code.

The integrated circuit may further comprise one or more bond pads electrically connectable to the plurality of identical circuits, wherein the hard-coded IC-specific code is readable from the one or more bond pads.

Aspects and embodiments of the invention are further described in the following description and in the claims.

### BRIEF DESCRIPTION OF THE DRAWINGS

Embodiments will now be described, by way of example only, with reference to the accompanying schematic drawings in which corresponding reference symbols indicate corresponding parts, and in which:

FIG. 1 shows prior art manufacturing steps for manufacturing an IC;

FIG. 2 shows manufacturing steps for manufacturing an IC according to an aspect of the invention;

FIG. 3 shows manufacturing steps for manufacturing an IC according to an aspect of the invention;

FIG. 4 shows a legend for FIGS. 5-8;

FIGS. 5 to 7 show an example of manufacturing steps for manufacturing an IC according to an aspect of the invention;

FIGS. 8A to 8C show examples of an arrangement of programmable conductive connections and target portions on an IC;

FIGS. 9A and 9B show another example of an arrangement of programmable conductive connections and target portions on an IC; and

FIGS. 10 and 11 show further examples of manufacturing steps for manufacturing an IC according to an aspect of the invention.

The figures are intended for illustrative purposes only, and do not serve as restriction of the scope or the protection as laid down by the claims.

### DESCRIPTION OF EMBODIMENTS

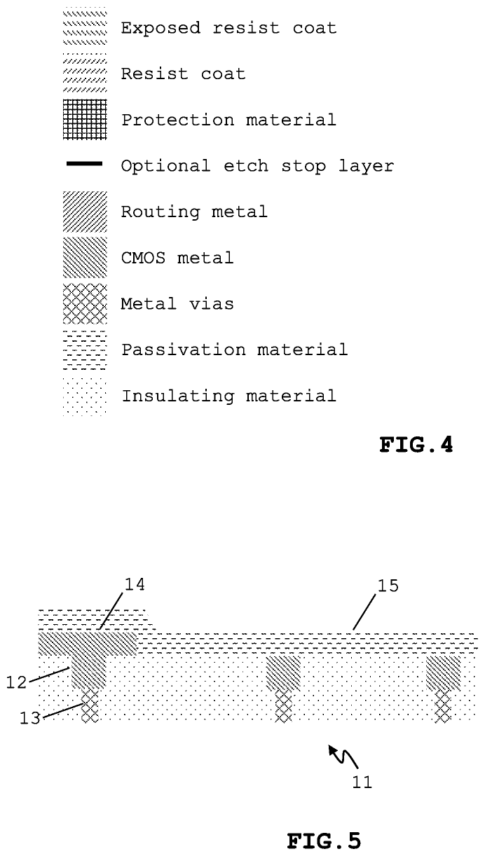

With reference to FIG. 2, the present disclosure provides a cost-effective method of hard-coding IC-specific information into a chip by adding an additional processing part to the overall manufacturing process. As shown in the FIG. 2, the manufacturing process includes conventional front-end process 1 (also referred to as first processing part 1), the additional mid-end process 3 for implementing the hard-coded information (also referred to as second processing part 3), and conventional back-end process 2. The front-end processing 1 may be located in a first environment, i.e. a semiconductor fab, and the mid-end process 3 may be located in a second environment separate from the first environment, e.g. a second semiconductor fab. Alternatively, both front-end and mid-end processes 1, 3 may be performed in the same fab. In the following non-limiting examples, the former applies.

By leaving the front-end production flow 1 unaltered, its cost effectiveness, fab yield, and full process qualification status can be maintained. Using a separate processing part such as mid-end process 3 with a dedicated interconnecting technology on top of the fully finished wafers from the front-end process 1, each chip can be cost efficiently manufactured with a predetermined IC-specific code, possibly a unique code that is used only once amongst a batch of chips (such as all the chips on one wafer or a series of wafers), possibly used only once amongst all chips. The IC-specific code may e.g. be used as an identifier in various types of applications including the domain of security applications.

Using full wafers for the coding process 30 in the mid-end processing 3 may result in a highly cost-effective solution, using for example a direct write lithography tool to realize the IC-specific code in each chip. The coding process 30 may use combinations of standard semiconductor materials. Different combinations of these semiconductor materials may provide robustness to process variations and minimize the impact on the CMOS chip performance and reliability.

The mid-end process 3 may complete a ROM code functionality that is designed and produced in the standard CMOS process 10 of the front-end process 1. For example, the mid-end process 3 may complete the last metal layer of a ROM to create a routing layer in the integrated circuit defining the code in the ROM of the integrated circuit. Hereto, the mid-end process 3 may add an additional metal layer that is connected to the last CMOS metal layer using “through passivation contacts” such as vias. The additional metal layer may be patterned in the mid-end process 3, resulting in individual connections between the bits of the ROM.

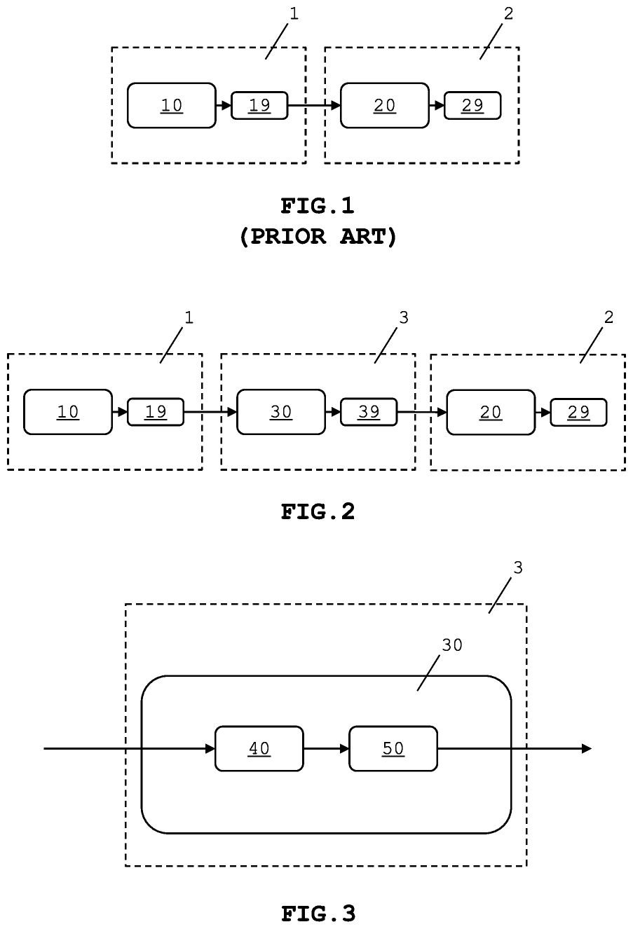

The manufactured integrated circuits including the ROM codes may be tested in a testing step 39 before the dies are assembled in back-end processing part 2, which may be similar to the back-end processing 2 shown in FIG. 1.

The processing steps of the mid-end processing 3 may be performed using CMOS processing materials and CMOS processing steps similar to the CMOS processing materials and CMOS processing steps used in the front-end processing 1. The required functionality to enable the mid-end processing 3 may be available through a “redistribution layer” (RDL) that is typically offered by CMOS foundries.

Any mid-end maskless lithography step may generate the hard-coded IC-specific code for each chip. Each code may be unique. A code in the form of binary information may be generated in the mid-end processing part 3 by locally and specifically etching the additional metal layer.

Materials used in the mid-end process 3 allow for optimization of the impact of this etching process and ensures that after the etching the materials are stable and protected. This may result in a lifetime performance equal to the standard CMOS process in the front-end 1.

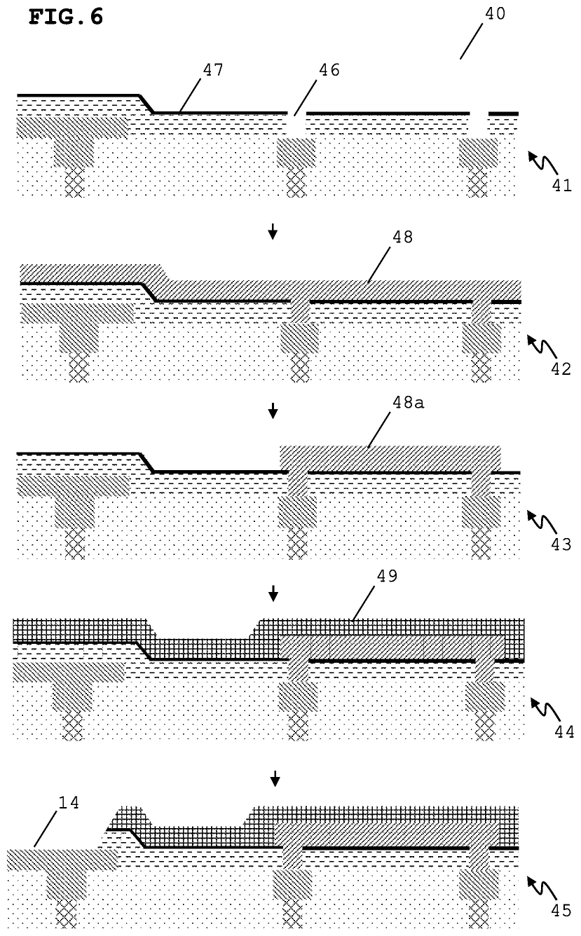

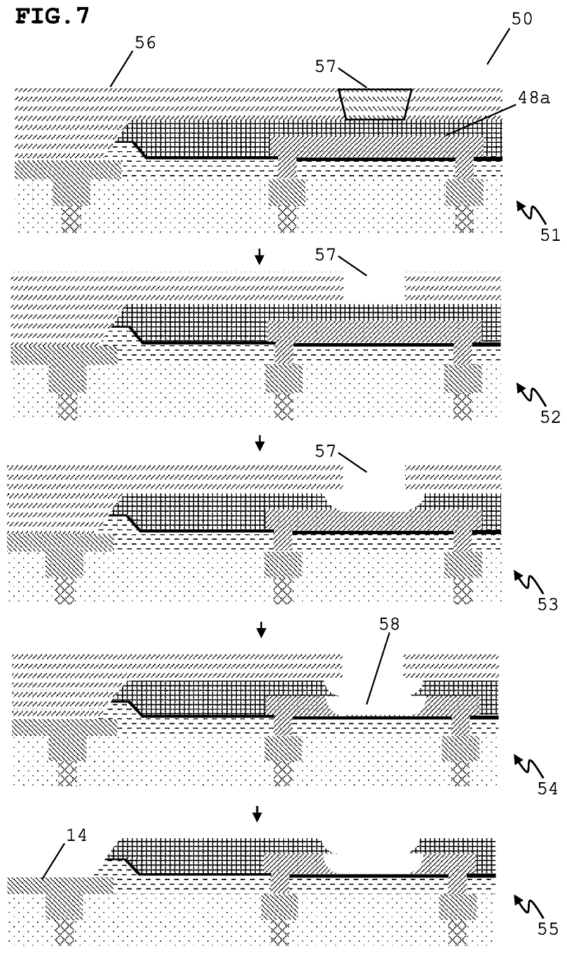

With reference to FIG. 3, the coding process 30 of the mid-end processing part 3 may include two phases: a first phase 40 wherein an additional routing layer is added on top of the standard passivation layer of the CMOS chip; and a second phase 50 wherein the additional routing layer is selectively etched to establish a hardware code ROM function. The two phases 40 and 50 will be further explained in FIGS. 4-9.

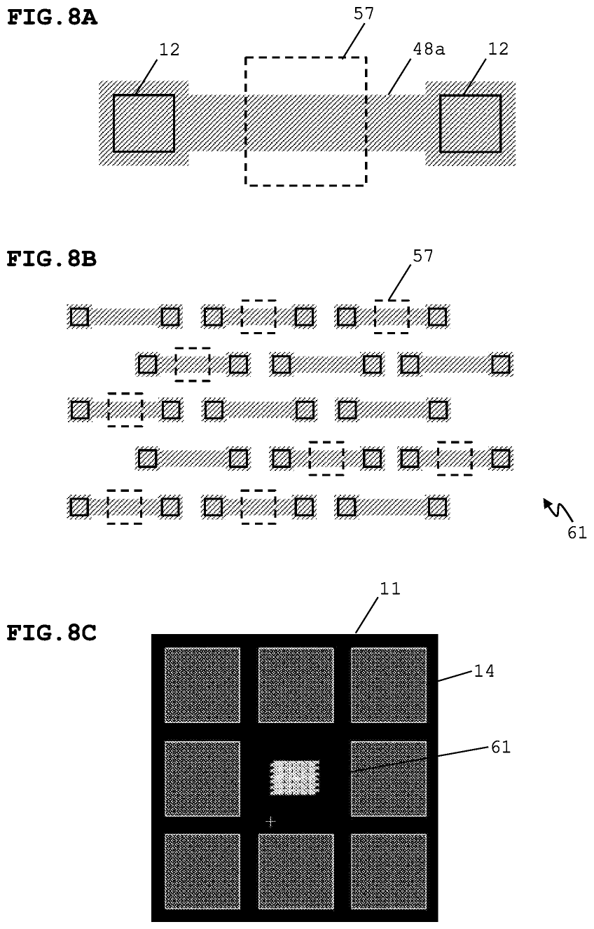

FIG. 4 shows a legend for FIGS. 5-9, indicating different materials that may be used in the layers created on the wafer and forming the ICs to be made from the wafer. As will be further explained in the examples of FIGS. 5-9, the insulating material, passivation material, through passivation contacts and CMOS metal are typically created in the front-end processing part 1. The routing metal, protection material and resist coat may be applied in the front-end processing part 1 or the mid-end processing part 3.

FIG. 5 is a schematic diagram showing a cross-section through a wafer. A large number of ICs have been formed on the wafer in front-end process 1, the ICs having identical circuits and being made using a conventional mask-based lithography process, preferably a CMOS process. FIG. 5 shows the wafer with IC 11 after completion of the conventional front-end process 1, before transferring the wafer to the manufacturing facility to perform the mid-end process 3. Only the upper layers of IC 11 are shown, including a metal routing layer 12 connected by metal vias or contacts 13 through one or more insulating layers to portions of the circuit of IC 11 formed on lower layers on the wafer. Bond pads 14, for connecting IC 11 to external components, are connected to the routing layer 12.

A passivation layer 15 is formed over the top of the wafer to seal and protect the underlying layers, and render the wafer with IC 11 inert, to avoid undesired interaction with air, moisture or other materials that may come into contact with the surface of the wafer. The passivation layer 15 may optionally be removed from a portion of the bond pads 14, as part of the conventional front-end process.

FIG. 6 shows an example of steps 41-45 that may be performed in the first phase 40 of the coding process 30.

In step 41, contact holes 46 are etched through the passivation layer 15 above portions of the routing metal layer 12. As show in step 41, an optional etch stop layer 47 may be formed on the passivation layer before etching. In step 42, routing metal deposition is performed, resulting in an additional metal layer 48 (or other conducting material such as polysilicon) being deposited on top of the passivation layer 15 and making contact with portions of the routing metal layer 12 of the IC created in the front-end process 1. This may be accomplished by forming conductive plugs (e.g. of Tungsten) in the contact holes 46 and subsequently forming the additional metal layer 48 over the top.

In step 43, patterning of the routing metal layer 48 is performed, resulting in selected parts of the additional metal layer 48 being removed. The remaining portions of the additional metal layer 48 form the programmable conductive connections 48a, used to make interconnections between two or more portions of the circuit of the IC 11.

Steps 41 to 43 are preferably performed using conventional mask-based lithography, and preferably using the same materials and processes as used in front-end process 1. Since the layout of the programmable conductive connections 48a is typically identical for every IC on the wafer, it is possible (and has advantages) to use conventional mask-based lithography tools and processes to reduce the cost of the mid-end process 3.

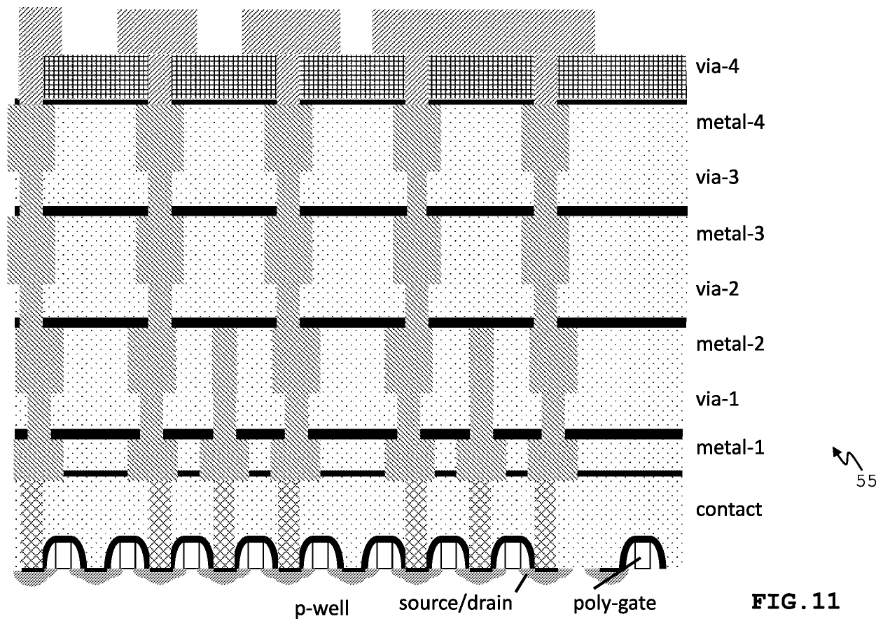

An example of the result of a step 43 is shown in FIG. 10, wherein a patterned additional metal layer 48 is shown as the top metal/conductive layer (FIG. 10 and FIG. 6 show different metal layer designs). The patterned additional layer and the vias in the via-4 layer created in the mid-end process 3 are connected to the layers below the via-4 layer including the CMOS elements (p-well, source/drain and poly-gate) forming the transistors of a ROM. In the example of FIG. 10, the additional metal layer is connected to the CMOS elements through a number of metal layers metal-1, metal-2, metal-3 and metal-4, a number of vias in via layers via-1, via-2, via-3 and via-4, and a number of contacts in the contact layer.

In step 44, an additional protection (passivation) layer 49 may be added. In step 45, the passivation layers 15 and 49 (and etch stop layer 47 if present) are removed from a portion of the bond pads 14 to permit a subsequent wire bonding operation during back-end processing 2.

FIG. 7 shows an example of steps 51-55 that may be performed in the second phase 50 of the coding process 30, on the wafer and IC 11 formed in the first phase 40 shown in FIG. 6.

In step 51, a coating of resist 56 is applied to the surface of the wafer and exposed in certain target portions 57, each target portion 57 comprising a small area overlying a portion of a corresponding programmable conductive connection 48a. The exposure of the target portions 57 is performed by a maskless lithography process. Conventional mask-based lithography is not suited for this step, since the set of target portions 57 to be exposed for each IC is different for different ICs on the wafer, and may be unique for every IC on the wafer. Since a conventional mask provides the pattern for only a small area of the wafer, and a conventional mask-based lithography tool repeatedly uses the same mask to progressively expose each area of the wafer, it is not feasible to use a mask to expose the target portions 57. Instead, a maskless lithography tool is preferably used to expose the selected set of target portions 57 for each IC 11.

In step 52, the resist is developed and removed from the exposed target areas, and in step 53 the passivation layer 49 is etched in the target areas 57, resulting in portions of certain selected ones of the interconnections 48a under the exposed set of target areas 57 being uncovered.

In step 54, the uncovered portions of the programmable conductive connections 48a are etched (typically using a conventional etching process) to remove the metal 58 of the selected interconnections 48a under the target areas 57. This results in breaking the interconnection formed between the circuit portions of the IC 11 which had been made by each of the selected programmable conductive connections 48a. In step 55, the resist is stripped and the top layer may be cleaned. The wafer is subsequently cut into pieces (diced) to separate each IC which then undergoes bank-end processing.

An example of the result of a step 55 is shown in FIG. 11, which is similar to FIG. 10 except for the top layer wherein the patterned additional metal layer has been altered by breaking connections resulting in an IC-specific code being hard-coded into the ROM of the integrated circuit (FIG. 11 and FIG. 7 show different metal layer designs).

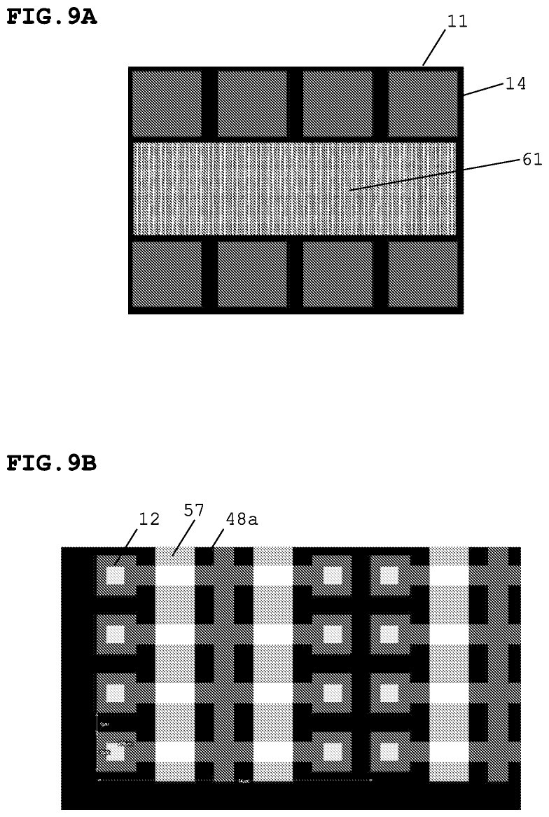

FIG. 8A is a schematic diagram showing a plan view of a single programmable conductive connection 48a. The programmable conductive connections 48a are formed in the shape of an elongated line of conductive material (e.g. metal), arranged between two portions of the underlying metal routing layer 12 to which the programmable conductive connection 48a is connected. A target portion 57 is located over a central part of the programmable conductive connection 48a, and is slightly wider than the width of the elongated line. For example, the elongated line may be 4 microns in length and 1 micron in width, with a target portion 3 microns wide and 2 microns long over the central portion of the elongated line.

FIG. 8B is a schematic diagram showing a plan view of a portion of an array 61 of programmable conductive connections 48a and corresponding selected target portions 57. The programmable conductive connections 48a are arranged in a regular array with the same distance separating the central part of each connection 48a (where a target portion 57 may be located) from adjacent central parts in x and y directions. For example, the array 61 may comprise 128 programmable conductive connections 48 a and 128 target portions 57, for storing a 128-bit binary code in the IC. Larger or smaller arrays 61 may be implemented, depending on the size of the code to be programmed into the IC.

FIG. 8C is a schematic diagram showing a plan view of a complete IC 11, showing an example of an arrangement of bond pads 14 and an array 61 of programmable conductive connections 48a and target portions 57. The IC-specific code hard-coded into the IC 11 may be accessed by external components by reading the code via the bond pads 14. For example, a standardized serial peripheral interface (SPI) may be implemented in the IC 11 and used to read the IC-specific code from the IC 11.

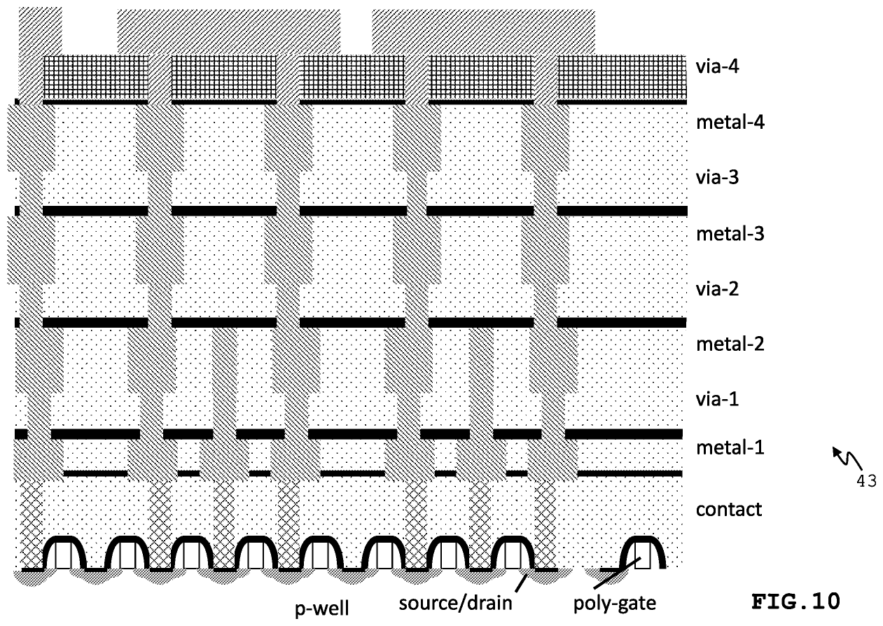

FIG. 9A is a schematic diagram showing a plan view of another example of a complete IC 11 having the same general structure as described above, but having a different arrangement of bond pads 14 and of the programmable conductive connections 48a and target portions 57 in the array 61. FIG. 9B is an enlarged plan view of a portion of the array 61 of programmable conductive connections 48a and corresponding selected target portions 57. In this example, the central parts of each programmable conductive connection 48a (where the target portions 57 may be located) are aligned in columns, so that the target portions 57 are aligned in multiple columns. Each column of target portions can be exposed by scanning a light beam or electron beam along the column and modulating the beam to selectively expose selected ones of the target portions 57. The horizontally-aligned programmable conductive connections 48a may be arranged with equal spacing between them in each column, to further simplify control of the exposure beam modulation. For example, each programmable conductive connection 48a in this arrangement may have one end electrically connected a common voltage line (e.g. a 3V or 0V line) and the other end electrically connected to a separate logic circuit or memory cell, to implement a modified circuit that stores a binary code.

The IC 11 may be dedicated to the function of storing the hard-coded IC-specific code, i.e. the function provided by IC 11 may be limited to outputting the IC-specific code upon request. This design enables production of the IC 11 which is as simple and cheap as possible.

The IC 11 may be packaged in a miniature SO8 package, e.g. suitable for board-level applications, or may use any other suitable packaging such as SSOP8, TSSOP8, 8WLCSP, or various leadless packages. IC 11 may be integrated in a multi-chip package, or integrated as an IP block in a larger IC. In some embodiments, IC 11 may implement an RF-ID function to enable contactless reading of the IC-specific code.

Thus, the invention as described herein enables production of small low-cost integrated circuits which have an IC-specific code permanently stored in the structure of the integrated circuit. The scope of the invention is not limited to the embodiments and examples. Rather, many variations of these embodiments and examples will be apparent to the skilled person, using the solution proposed, including a definition by way of the following clauses.

1. A method of manufacturing a one time programmable, immutable integrated circuit comprising device, having a predetermined IC-specific, unique code, hard-coded into the structure of the integrated circuit, the method comprising:
forming a plurality of identical integrated circuits in a plurality of first layers on a wafer using a first processing part, the first processing part comprising forming a first passivation layer over the first layers; and
processing the wafer including the plurality of identical integrated circuits in a second processing part using a maskless lithography process, the processing comprising:
forming a plurality of programmable conductive connections in at least one further circuit layer, applied on the wafer in said second processing part, wherein the plurality of programmable conductive connections each make interconnections between two or more circuit portions of the plurality of identical integrated circuits, and wherein the plurality of programmable conductive connections each comprise a target portion, the target portions being arranged in an array at predetermined positions on the wafer;
exposing a selected set of the target portions, wherein the selected set of the target portions is different for different ones of the plurality of identical integrated circuits on the wafer;
etching the wafer to remove portions of the programmable conductive connections at the exposed target portions to remove the interconnections between the circuit portions of the plurality of identical integrated circuits, wherein the remaining interconnections and the removed interconnections implement an IC-specific code in each one of the plurality of identical integrated circuits; and
cutting the wafer to separate the integrated circuit from the remaining ones of the plurality of identical integrated circuits.

2. The method according to claim 1, wherein the plurality of conductive connections formed in the second processing part are formed at least in part on top of the first passivation layer.

3. The method according to claim 1, further comprising forming a second passivation layer over the first passivation layer and the plurality of conductive connections.

4. The method according to claim 1, further comprising forming an etch stop layer formed over the first passivation layer, the plurality of programmable conductive connections being formed over the etch stop layer.

5. The method according to claim 1, wherein exposing the selected set of target portions comprises exposing the target portions with a maskless lithography tool.

6. The method according to claim 1, wherein the target portions are aligned in one or more rows or columns to enable exposure of the target portions by a scanning exposure beam.

7. The method according to claim 1, wherein the plurality of identical integrated circuits in combination with their respective remaining and removed interconnections each form a read-only memory storing the IC-specific code.

8. The method according to claim 1, wherein the second processing part uses substantially similar materials and substantially similar processing steps as used in the first processing part.

9. The method according to claim 1, wherein the hard-coded IC-specific code implemented in each one of the plurality of identical integrated circuits is different in different ones of the plurality of identical integrated circuits.

10. The method according to claim 1, wherein a different hard-coded IC-specific code is implemented in each one of the plurality of identical integrated circuits.

11. An integrated circuit manufactured in accordance with claim 1.

12. An integrated circuit having a predetermined IC-specific code hard-coded into the structure of the integrated circuit, comprising:
a plurality of identical circuits formed in a plurality of first layers, and
a plurality of programmable conductive connections each making an electrical interconnection between two or more circuit portions of a respective one of the plurality of identical circuits,
wherein the plurality of programmable conductive connections each comprise a target portion, the target portions being arranged at predetermined positions on a single layer; wherein selected ones of the target portions have been etched to remove portions of the respective programmable conductive connection at the respective target portion to break the interconnection between the respective circuit portions of the respective identical circuit, and wherein the remaining interconnections and the removed interconnections, in conjunction with the plurality of identical circuits, implement the hard-coded IC-specific code in the integrated circuit.

13. The integrated circuit device according to claim 12, further comprising a first passivation layer formed over the first layers, and wherein the plurality of conductive connections are formed at least in part over the first passivation layer.

14. The integrated circuit device according to claim 12, wherein the plurality of identical circuits in combination with their respective remaining and removed interconnections form a read-only memory storing the hard-coded IC-specific code.

15. The integrated circuit device according to claim 12, further comprising one or more bond pads electrically connectable to the plurality of identical circuits, wherein the hard-coded IC-specific code is readable from the one or more bond pads.

16. The method according to claim 1, wherein the first passivation layer covers bond pads of each integrated circuit.
